(19) United States
(12) Patent Application Publication
(10) Pub. No.: US 2025/0366204 A1
(43) Pub. Date: Nov. 27, 2025

(54) MULTI-STACK SEMICONDUCTOR DEVICE

(71) Applicant: Samsung Electronics Co., Ltd., Suwon-si (KR)

(72) Inventors: Jisoo Park, Suwon-si (KR); Junghan Lee, Suwon-si (KR); Byungsung Kim, Suwon-si (KR); Jaehyoung Lim, Suwon-si (KR); Kwanyoung Chun, Suwon-si (KR)

(21) Appl. No.: 19/203,314

(22) Filed: May 9, 2025

(30) Foreign Application Priority Data
May 24, 2024 (KR) 10-2024-0067904

(51) Int. Cl. H10D 84/90; H10D 89/10

(52) U.S. Cl. CPC H10D 84/975; H10D 84/953; H10D 84/981; H10D 89/10

(57) ABSTRACT

Provided is a multi-stack semiconductor device including a back-side wiring layer having a first back-side line and a second back-side line each extending in a first horizontal direction, a first FET on the back-side wiring layer and including a lower source/drain region, a second FET on the first FET and including an upper source/drain region, and a hybrid tap cell having a first tap cell and a second tap cell that are adjacent to each other in a second horizontal direction perpendicular to the first horizontal direction, wherein the first tap cell includes a first through structure electrically connected to the first back-side line, and the second tap cell comprises a second through structure extending through an upper dummy source/drain region and electrically connected to the second back-side line, where the upper dummy source/drain region is spaced apart from the upper source/drain region in the first horizontal direction.

### CROSS-REFERENCE TO RELATED APPLICATIONS

This application is based on and claims priority under 35 U.S.C. § 119 to Korean Patent Application No. 10-2024-0067904, filed on May 24, 2024, in the Korean Intellectual Property Office, the disclosure of which is incorporated by reference herein in its entirety.

### BACKGROUND OF THE INVENTION

The inventive concepts relate to a multi-stack semiconductor device, and more particularly, to a multi-stack semiconductor device stacked vertically.

Recently, down-scaling of semiconductor devices is progressing rapidly. Additionally, the structure of transistors included in semiconductor devices is being optimized because the semiconductor devices require not only high operating speeds but also operational accuracy. In particular, as semiconductor devices become more highly integrated, semiconductor devices may be composed of three-dimensional (3D) transistors with a multi-gate structure. For example, 3D transistors may be implemented with a gate surrounding an active pin.

### SUMMARY OF THE INVENTION

The inventive concepts provide a multi-stack semiconductor device capable of securing a sufficient area of the logic cell by using a hybrid tap cell that includes a power tap cell and a signal tap cell in one cell region.

The inventive concepts are not limited to that mentioned above, and other inventive concepts not mentioned will be clearly understood by those skilled in the art from the description below.

According to aspects of the inventive concepts, there is provided a multi-stack semiconductor device including a back-side wiring layer having a first back-side line and a second back-side line each extending in a first horizontal direction, a first field-effect transistor (FET) on the back-side wiring layer and including a lower source/drain region, a second FET on the first FET and including an upper source/drain region on the lower source/drain region, and a hybrid tap cell having a first tap cell and a second tap cell that are adjacent to each other in a second horizontal direction perpendicular to the first horizontal direction, wherein the first tap cell includes a first through structure electrically connected to the first back-side line in a vertical direction, and wherein the second tap cell includes a second through structure extending through an upper dummy source/drain region and electrically connected to the second back-side line in the vertical direction, where the upper dummy source/drain region is spaced apart from the upper source/drain region in the first horizontal direction.

According to aspects of the inventive concepts, there is provided a multi-stack semiconductor device including a hybrid tap cell on a side of a plurality of logic cells and having a power tap cell and a signal tap cell in a cell region, a back-side wiring layer having a back-side power line and a back-side signal line each extending in a first horizontal direction, in the plurality of logic cells and the hybrid tap cell, a first field-effect transistor (FET) on the back-side wiring layer and a second FET on the first FET, in one or more of the plurality of logic cells, a front-side wiring layer on the second FET and having a front-side power line and a plurality of front-side signal lines each extending in the first horizontal direction, in the plurality of logic cells and the hybrid tap cell, a power through structure electrically connecting the front-side power line to the back-side power line in a vertical direction, in the power tap cell of the hybrid tap cell, and a signal through structure electrically connecting at least one of the plurality of front-side signal lines to the back-side signal line in the vertical direction, in the signal tap cell of the hybrid tap cell.

According to aspects of the inventive concepts, there is provided a multi-stack semiconductor device including a back-side wiring layer having a first back-side line and a second back-side line each extending in a first horizontal direction, a first field-effect transistor (FET) on the back-side wiring layer, a second FET on the first FET, a front-side wiring layer on the second FET and having a first front-side line and a second front-side line each extending in the first horizontal direction, a hybrid tap cell including, in a cell region, a power tap cell and a signal tap cell that are adjacent to each other in a second horizontal direction perpendicular to the first horizontal direction, a first through structure electrically connecting the first front-side line to the first back-side line in a vertical direction and including a first upper via and a first through electrode in the power tap cell, and a second through structure electrically connecting the second front-side line to the second back-side line in the vertical direction and including a second upper via, an upper contact, a second through electrode, a lower source/drain contact, a lower contact, and a lower via in the signal tap cell, wherein each of the first FET and the second FET includes a gate extending in the second horizontal direction, source/drain regions on opposite sides of the gate in the first horizontal direction, and a channel region between the source/drain regions and at least partially surrounded by the gate, wherein first ones of the source/drain regions include an active source/drain region and second ones of the source/drain regions include a dummy source/drain region, and wherein the first through electrode does not extend into the dummy source/drain region, and the second through electrode extends into the dummy source/drain region.

### BRIEF DESCRIPTION OF THE DRAWINGS

Example embodiments will be more clearly understood from the following detailed description taken in conjunction with the accompanying drawings, in which:

FIG. 1 is a plan view of a multi-stack semiconductor device according to some embodiments;

FIGS. 2A and 2B are plan views of a logic cell of the multi-stack semiconductor device of FIG. 1;

FIG. 3 is a cross-sectional view taken along line I-I′ in FIGS. 2A and 2B;

FIG. 4A is a plan view showing a hybrid tap cell of the multi-stack semiconductor device of FIG. 1;

FIG. 4B is a cross-sectional view taken along line II-II′ in FIG. 4A;

FIG. 4C is a cross-sectional view taken along line III-III′ in FIG. 4A;

FIG. 5 is a conceptual diagram showing arrangement structures of different types of cells; and

FIGS. 6 to 10 are diagrams of multi-stack semiconductor devices according to some embodiments.

### DETAILED DESCRIPTION

Hereinafter, example embodiments are described in detail with reference to the attached drawings.

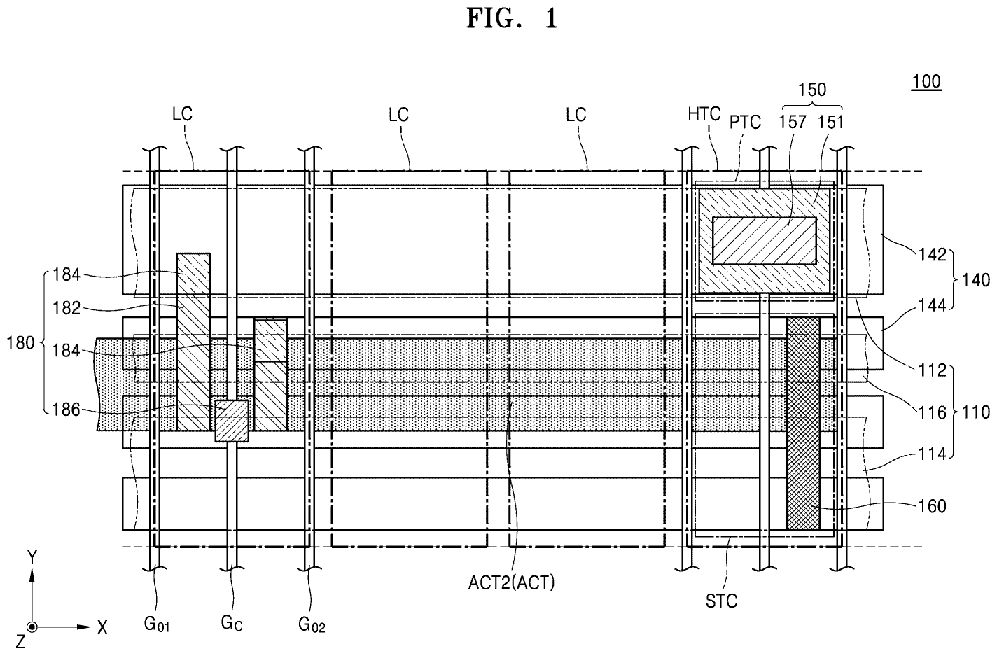

FIG. 1 is a plan view of a multi-stack semiconductor device according to some embodiments.

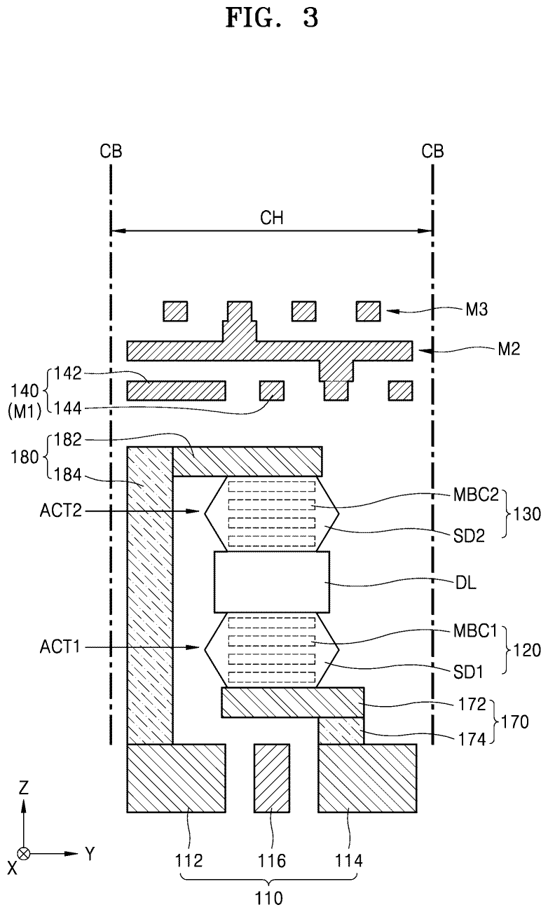

Referring to FIG. 1, a multi-stack semiconductor device 100 according to some embodiments may include a back-side wiring layer 110, a first field-effect transistor (FET) 120 (see FIG. 3), a second FET 130 (see FIG. 3), a front-side wiring layer 140, a first through structure 150, and a second through structure 160. As used herein, the first through structure 150 may also be referred to as a power through structure, and the second through structure 160 may also be referred to as a signal through structure.

The back side may refer to a lower side in a vertical direction (Z direction) and the front side may refer to an upper side in the vertical direction (Z direction). For example, the back-side wiring layer 110, the first FET 120, the second FET 130, and the front-side wiring layer 140 may be sequentially arranged in the vertical direction (Z direction).

The back-side wiring layer 110 may include a first back-side power line 112, a second back-side power line 114, a back-side signal line 116, and a back-side connection line 118. The first back-side power line 112 and the second back-side power line 114 may be referred to as first back-side lines and the back-side signal line 116 may be referred to as a second back-side line.

The first back-side power line 112 may extend in a first horizontal direction (X direction). The first back-side power line 112 may provide a first power, e.g., a power of a negative (−) potential or a ground potential, to the first FET 120 and the second FET 130.

The second back-side power line 114 may be spaced apart from the first back-side power line 112 in a second horizontal direction (Y direction) and may extend in the first horizontal direction (X direction). The second back-side power line 114 may provide a second power, e.g., a power of a positive (+) potential, to the first FET 120 and the second FET 130. For example, the second horizontal direction (Y direction) may be perpendicular to the first horizontal direction (X direction).

The back-side signal line 116 may be arranged between the first back-side power line 112 and the second back-side power line 114 in the second horizontal direction (Y direction) and may extend in the first horizontal direction (X direction). In some embodiments, the back-side signal line 116 may be electrically connected to a first source/drain SD1 (see FIG. 3) of the first FET 120 by contacting the same. In other words, signals may be input and output to the first FET 120 through the back-side signal line 116. As used herein, the first source/drain SD1 may also be referred to as a first source/drain region or a lower source/drain region.

The back-side connection line 118 may be arranged below the first back-side power line 112, the second back-side power line 114, and the back-side signal line 116 and may electrically connect the same, if necessary.

In the multi-stack semiconductor device 100 according to some embodiments, the first back-side power line 112 and the second back-side power line 114 may be alternately arranged with the back-side signal line 116 positioned in between in the second horizontal direction (Y direction). As shown in the drawings, the first back-side power line 112, the back-side signal line 116, and the second back-side power line 114 may constitute one cell in the second horizontal direction (Y direction).

The first FET 120 may be located above the back-side wiring layer 110 in the vertical direction (Z direction). In addition, the second FET 130 may be located above the first FET 120 in the vertical direction (Z direction). In other words, the second FET 130 may be stacked above the first FET 120. As such, the multi-stack semiconductor device 100 according to some embodiments may have a structure in which two FETs are stacked in the vertical direction (Z direction).

In some embodiments, the first FET 120 may include a pMOSFET and the second FET 130 may include an nMOSFET. In other embodiments, the first FET 120 may include an nMOSFET and the second FET 130 may include a pMOSFET.

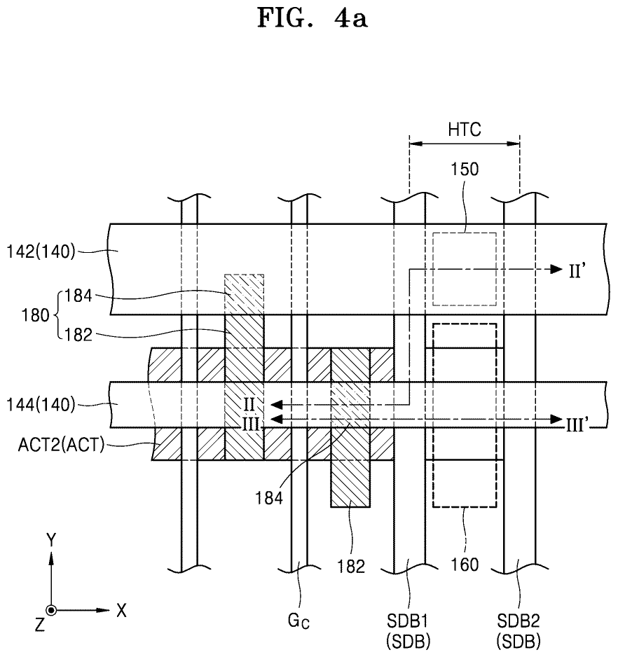

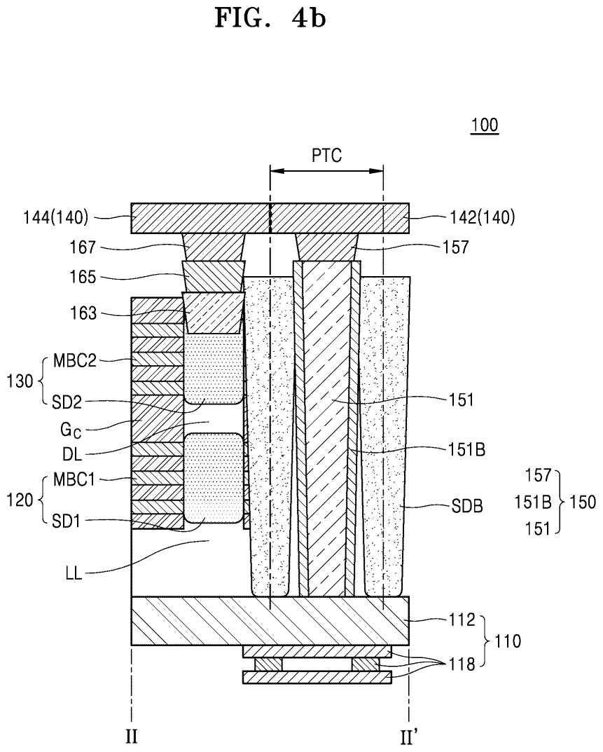

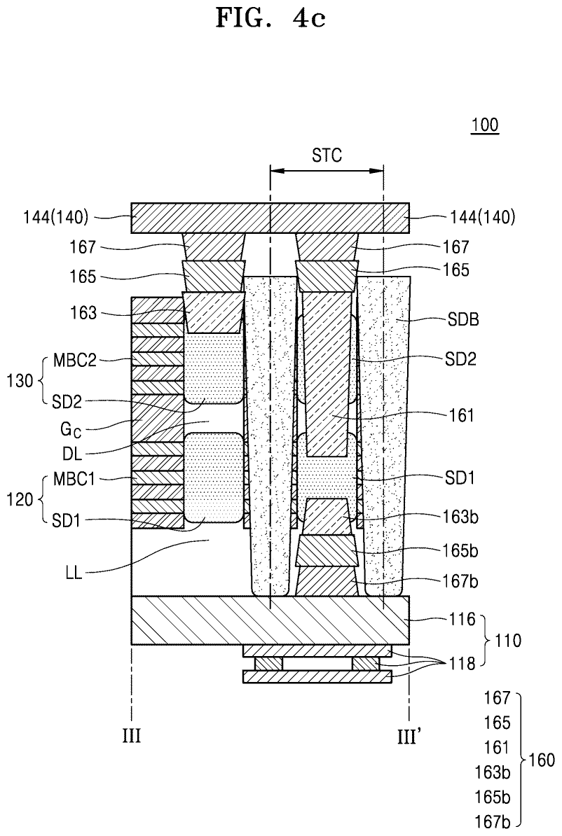

The first FET 120 and the second FET 130, each including a gate Gc, may include first and second sources/drains SD1 and SD2 (see FIG. 3) and first and second channels MBC1 and MBC2 (see FIG. 3), respectively. Specifically, the first FET 120 may include the gate Gc, the first source/drain SD1, and the first channel MBC1, and the second FET 130 may include the gate Gc, the second source/drain SD2, and the second channel MBC2. As used herein, the second source/drain SD2 may also be referred to as a second source/drain region or an upper source/drain region. The first FET 120 and the second FET 130 may share the gate Gc. In other embodiments, the gate of the first FET 120 may be separate from the gate of the second FET 130. FIG. 4B illustrates an embodiment in which the gate of the first FET 120 and the gate of the second FET 130 are integrally formed. However, in some embodiments, when the gate of the first FET 120 and the gate of the second FET 130 are separately arranged, a dielectric layer may be located between an upper gate and a lower gate.

The gate Gc may extend in the second horizontal direction (Y direction). The gate Gc may surround the first channel MBC1 and the second channel MBC2 in a gate-all-around (GAA) structure. The actives ACT may extend in the first horizontal direction (X direction) and may include a lower first active ACT1 (see FIG. 3) and an upper second active ACT2. As used herein, the lower first active ACT1 may also be referred to as a lower first active region, and the upper second active ACT2 may also be referred to as an upper second active region. Additionally, a gate via 186 may be located above the gate Gc and may be connected to a front-side signal line 144 of the front-side wiring layer 140.

The first active ACT1 may configure the first source/drain SD1 and the first channel MBC1, and the second active ACT2 may configure the second source/drain SD2 and the second channel MBC2. The first active ACT1 and the second active ACT2 may be electrically separated by a dielectric layer DL.

Each of the first source/drain SD1 and the second source/drain SD2 may include one of silicon (Si) or silicon germanium (SiGe). For example, the first source/drain SD1 and the second source/drain SD2 may both include Si, or the first source/drain SD1 and the second source/drain SD2 may both include SiGe. In some embodiments, the first source/drain SD1 may include any one of Si or SiGe, and the second source/drain SD2 may include the other one of Si or SiGe.

Specifically, in the first FET 120, the first active ACT1 on both (i.e., opposite) sides of the gate Gc may configure the first source/drain SD1 in the first horizontal direction (X direction), and the first active ACT1 between both sides of the first source/drain SD1 may configure the first channel MBC1. In addition, in the second FET 130, the second active ACT2 on both sides of the gate Gc may configure the second source/drain SD2 in the first horizontal direction (X direction), and the second active ACT2 between both sides of the second source/drain S2 may configure the second channel MBC2.

Each of the first channel MBC1 and the second channel MBC2 may include a plurality of semiconductor patterns. For example, the plurality of semiconductor patterns may be spaced apart from each other in the vertical direction (Z direction) to have a nano-sheet shape. In addition, four sides of each of the plurality of semiconductor patterns may be surrounded by the gate Gc. In other words, each of the first channel MBC1 and the second channel MBC2 may have a multi-bridge channel (MBC) structure. The four sides may include both sides in the second horizontal direction (Y direction) and both sides in the vertical direction (Z direction). In some embodiments, each of the first channel MBC1 and the second channel MBC2 may include at least two nano-sheets. In other embodiments, at least one of the first channel MBC1 and the second channel MBC2 may include only one nano-sheet. As used herein, the first channel MBC1 may also be referred to as a first channel region, and the second channel MBC2 may also be referred to as a second channel region.

In the multi-stack semiconductor device 100 according to some embodiments, the logic cell LC may correspond to, for example, a standard cell or a unit cell and may be used as a basic layout in the process of designing an integrated circuit.

For reference, to briefly explain the standard cell, as semiconductor devices become highly integrated, a lot of time and cost may be required to design the layout, especially for device regions, of the integrated circuit. Therefore, as a technique for saving the time and cost, a standard cell-based layout design technique may be used. The standard cell-based layout design technique may reduce the time required for layout design by designing logic elements, such as OR gates or AND gates, that are repeatedly used as standard cells in advance and storing the same in a computer system and then placing the same where necessary for layout design.

For example, the standard cell may include a basic cell, such as AND, OR, NOR, inverter, NAND, and NOR, a complex cell, such as OR/AND/INVERTER (OAI) and AND/OR/INVERTER (AOI), and a storage element, such as a simple master-slave flip-flop and a latch.

The logic cell LC of the multi-stack semiconductor device 100 according to some embodiments may include, for example, an inverter. The logic cell LC is not limited to an inverter and may include other logic elements.

In some embodiments, the first source/drain SD1 of the first FET 120 may be connected to the second back-side power line 114 through a lower contact structure 170, and the second source/drain SD2 of the second FET 130 may be connected to the first back-side power line 112 through an upper contact structure 180.

The front-side wiring layer 140 may include a front-side power line 142 and a plurality of front-side signal lines 144. The front-side power line 142 may be referred to as a first front-side line and the plurality of front-side signal lines 144 may be referred to as second front-side lines.

The front-side power line 142 may extend in the first horizontal direction (X direction). The front-side power line 142 may provide the second FET 130 with a first power, e.g., a power of a negative (−) potential or a ground potential. The front-side power line 142 may be connected to the first back-side power line 112 through the first through structure 150 in the power tap cell PTC.

The plurality of front-side signal lines 144 may be spaced apart from each other in the second horizontal direction (Y direction) and may extend in the first horizontal direction (X direction). In some embodiments, signals may be input and output to the second FET 130 through the plurality of front-side signal lines 144.

Wiring layers M1, M2, and M3 (see FIG. 3) arranged in a multilayer structure may be located above the second FET 130. For example, the front-side wiring layer 140 may correspond to a lowermost wiring layer among the wiring layers M1, M2, and M3, e.g., the first wiring layer M1 (see FIG. 3), but is not limited thereto.

In the multi-stack semiconductor device 100 according to some embodiments, the hybrid tap cell HTC may include both the power tap cell PTC and the signal tap cell STC arranged side by side in the second horizontal direction (Y direction) in one cell region. In other words, the power tap cell PTC and the signal tap cell STC may be in one cell region and may be adjacent to each other in the second horizontal direction (Y direction). The power tap cell PTC may be referred to as a first tap cell and the signal tap cell STC may be referred to as a second tap cell.

In some embodiments, one hybrid tap cell HTC may be arranged for every several to several tens of contact poly pitches (CPPs) in the first horizontal direction (X direction). For example, the hybrid tap cell HTC may be arranged for every 60 CPPs. In some embodiments, the hybrid tap cell HTC may be arranged after every predetermined number of logic cells LC in the first horizontal direction (X direction).

For reference, the CPP may refer to a pitch of a gate in the first horizontal direction (X direction). In addition, in the multi-stack semiconductor device 100 according to some embodiments, two CPPs may constitute one logic cell LC. Specifically, the logic cell LC may be defined as a region up to a half of each of two outer gates Go1 and Go2 with respect to the central gate Gc in the first horizontal direction (X direction) and a region including the first back-side power line 112 and the second back-side power line 114 in the second horizontal direction (Y direction). In other words, the logic cell LC may be defined as a region extending between the midpoint of two outer gates Go1 and Go2, with respect to the central gate Gc, in the first horizontal direction (X direction) and a region including the first back-side power line 112 and the second back-side power line 114 in the second horizontal direction (Y direction).

The logic cell LC may be arranged in a two-dimensional array structure in the first horizontal direction (X direction) and the second horizontal direction (Y direction). A width of one logic cell LC in the second horizontal direction (Y direction) may have a cell height CH and a plurality of logic cells LCs may be arranged in the first horizontal direction (X direction). For convenience of explanation, only one logic cell LC is illustrated in some of the drawings but a plurality of logic cells LCs may be arranged side by side in the first horizontal direction (X direction).

Although the components of the logic cell LC are shown only in the leftmost logic cell LC in FIG. 1 for convenience of explanation and understanding, the components of the logic cell LC are also equally or similarly applied to the right logic cells LC.

The hybrid tap cell HTC may be located on one side or both sides of the plurality of logic cell LCs. For example, it is shown that the hybrid tap cell HTG is located at a right end of the plurality of logic cell LCs in the first horizontal direction (X direction). In some embodiments, the hybrid tap cell HTC may be arranged after every predetermined number of logic cells LC in the first horizontal direction (X direction).

In some embodiments, the front-side power line 142 and the first back-side power line 112 may cross the power tap cell PTC, and the plurality of front-side signal lines 144 and the back-side signal line 116 may cross the signal tap cell STC.

In the multi-stack semiconductor device 100 according to some embodiments, the first through structure 150 that connects the first back-side power line 112 to the front-side power line 142 in the vertical direction (Z direction) may be located in the power tap cell PTC, and the second through structure 160 that connects the back-side signal line 116 to the plurality of front-side signal lines 144 in the vertical direction (Z direction) may be located in the signal tap cell STC. In other words, the first through structure 150 and the second through structure 160 may be arranged side by side in the second horizontal direction (Y direction).

Accordingly, in the hybrid tap cell HTC, the front-side power line 142, the first back-side power line 112, the second back-side power line 114, and the first through structure 150 may function as a power distribution network, and the plurality of front-side signal lines 144, the back-side signal line 116, and the second through structure 160 may function as a signal distribution network.

Ultimately, the multi-stack semiconductor device 100 according to the inventive concepts has an effect of increasing the integration because the area of the logic cell LC may be sufficiently secured by using the hybrid tap cell HTC including the power tap cell PTC and the signal tap cell STC in one cell region.

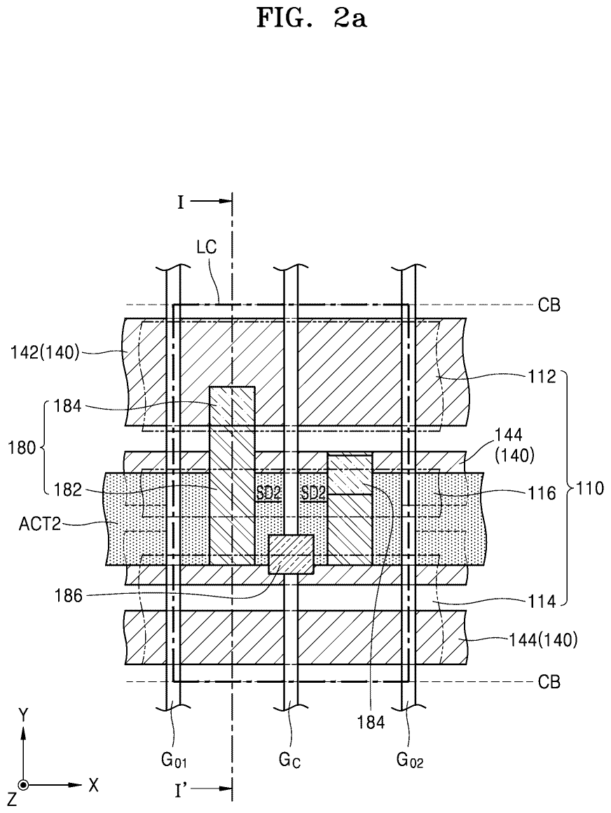

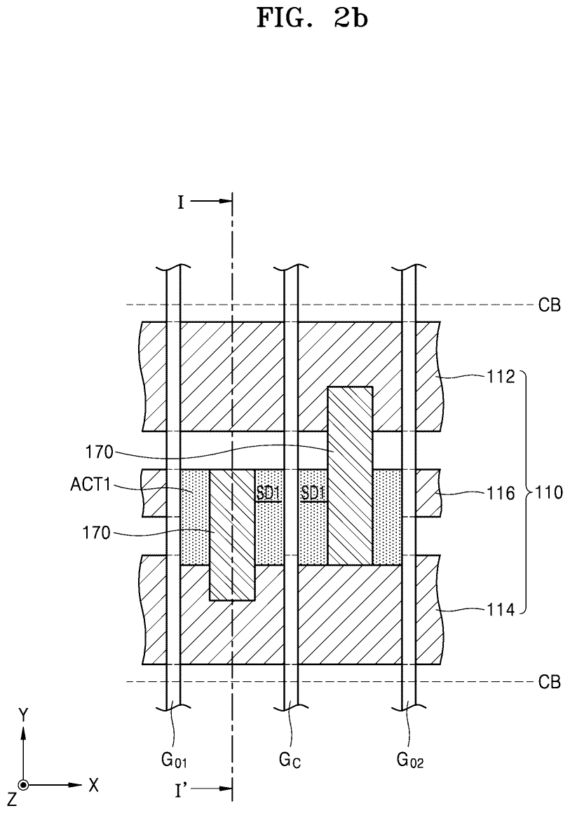

FIGS. 2A and 2B are plan views of a logic cell of the multi-stack semiconductor device of FIG. 1. FIG. 3 is a cross-sectional view taken along line I-I′ in FIGS. 2A and 2B.

For convenience of explanation, description is given with reference to FIG. 1 and details already described with reference to FIG. 1 are briefly described or omitted.

Referring to FIGS. 2A, 2B, and 3 together, the multi-stack semiconductor device 100 according to some embodiments may include logic elements in the logic cell LC.

In some embodiments, the first FET 120 may include a pMOSFET and the second FET 130 may include an nMOSFET. In other embodiments, the vertical positions of the first FET 120 and the second FET 130 may be changed.

FIGS. 2A and 2B are plan views with different vertical levels in the vertical direction (Z direction). FIG. 2A is a top view of the front-side wiring layer 140, showing the second FET 130. FIG. 2B is a top view of the first active ACT1, showing the first FET 120.

Thus, the cutting lines of I-I′ in FIGS. 2A and 2B may be the same. In other words, a cross-sectional view taken along the line I-I′ in FIG. 2A may correspond to an area from the second FET 130 to the front-side wiring layer 140 in the cross-sectional view of FIG. 3, and a cross-sectional view taken along the line I-I′ in FIG. 2B may correspond to an area from the back-side wiring layer 110 to the first FET 120 in the cross-sectional view of FIG. 3.

Due to the location of the cutting line I-I′ in the first horizontal direction (X direction), the first and second channels MBC1 and MBC2 may not be shown in FIG. 3. In other words, the first and second channels MBC1 and MBC2 may be located at locations corresponding to the gate Gc in the first horizontal direction (X direction) and may be surrounded by the gate Gc. In fact, the first and second channels MBC1 and MBC2 may be shown when cutting part of the gate Gc.

Accordingly, in FIG. 3, the first and second channels MBC1 and MBC2 may be indicated by dashed lines and may be located inside or outside the paper plane in the first horizontal direction (X direction). In FIG. 3, the cell height CH of the logic cell LC in the second horizontal direction (Y direction) is indicated by double arrows.

In addition, in FIG. 2A, a rectangular area surrounded by bold dash-dotted lines may correspond to the logic cell LC. A boundary of the logic cell LC in the second horizontal direction (Y direction) may correspond to a cell boundary CB. In addition, a boundary of the logic cell LC in the first horizontal direction (X direction) may correspond to a half (i.e., midpoint) of each of the outer gates Go1 and Go2 located on both sides of the center gate Gc.

Specifically, a connection relationship between the first FET 120 and the second FET 130 and the back-side wiring layer 110 and the front-side wiring layer 140 is described as follows.

As shown in FIG. 2B, in the first FET 120, the first source/drain SD1 may be located on both sides of the gate Gc in the first horizontal direction (X direction). In addition, as shown in FIG. 2A, in the second FET 130, the second source/drain SD2 may be located on both sides of the gate Gc in the first horizontal direction (X direction).

As shown in FIG. 3, the first source/drain SD1 of the first FET 120 may be connected to the second back-side power line 114 through the lower contact structure 170. For example, the lower contact structure 170 may include a first source/drain contact 172 and a first power via 174. The first source/drain contact 172 may contact the first source/drain SD1 and extend in the second horizontal direction (Y direction). The first power via 174 may connect the first source/drain contact 172 to the second back-side power line 114. Accordingly, at least a portion of the first source/drain contact 172 may overlap the second back-side power line 114 in the vertical direction (Z direction), and the first power via 174 located in the overlapped portion may connect the first source/drain contact 172 to the second back-side power line 114. As used herein, “an element A overlaps an element B in a first direction” (or similar language) means that there is at least one straight line that extends in the first direction and intersects both the elements A and B.

Additionally, the second source/drain SD2 of the second FET 130 may be connected to the first back-side power line 112 through the upper contact structure 180. The upper contact structure 180 may include a second source/drain contact 182 and a second power via 184. In addition, the upper contact structure 180 may further include a gate via 186.

The second source/drain contact 182 may contact the second source/drain SD2 and extend in the second horizontal direction (Y direction). The second power via 184 may connect the second source/drain contact 182 to the first back-side power line 112. Accordingly, at least a portion of the second source/drain contact 182 may overlap the first back-side power line 112 in the vertical direction (Z direction), and the second power via 184 located in the overlapped portion may connect the second source/drain contact 182 to the first back-side power line 112.

In some embodiments, actives ACT may include semiconductor materials, such as Si, SiGe, Ge, GaAs, InSb, GaP, GaSb, InAlAs, InGaAs, GaSbP, GaAsSb, and InP. In the multi-stack semiconductor device 100 according to some embodiments, the actives ACT may include Si or SiGe.

Each of the gate Gc and the outer gates Go1 and Go2 may include a gate dielectric layer and a gate electrode layer. The gate dielectric layer may include, for example, silicon oxide, silicon nitride, a high-k dielectric material, and/or a combination thereof.

In some embodiments, the gate dielectric layer may include an interface layer formed between the channel layers and the dielectric material. In some embodiments, the gate dielectric layer may be formed using an atomic layer deposition (ALD) process to have a uniform thickness around the respective channel layers. The method of forming the gate dielectric layer is not limited to the ALD process.

The gate electrode layer may be formed on the gate dielectric layer to surround the first and second channels MBC1 and MBC2. The gate electrode layer may include polysilicon, aluminum (Al), titanium (Ti), tantalum (Ta), tungsten (W), cobalt (Co), molybdenum (Mo), tantalum nitride (TaN), nickel silicide (NiSi), CoSi, TIN, WN, TiAl, TiAlN, TaCN, TaC, TaSiN, metal alloys, and/or a combination thereof.

The gate electrode layer may further include one or more work function adjustment layers. The work function adjustment layer may be arranged on the gate dielectric layer. The work function adjustment layer may include TiN, TaN, TaAlC, TiC, TaC, Co, Al, TiAl, HfTi, TiSi, TaSi, TiAlC, and/or a combination thereof.

The first and second source/drain contacts 172 and 182 and the first and second power vias 174 and 184 connected to the first FET 120 and the second FET 130, respectively, may include Co, Ni, W, Ti, Ta, copper (Cu), Al, TiN, TaN, and/or a combination thereof. In some embodiments, a silicide layer may be formed between the first source/drain SD1 and the first source/drain contact 172, and between the second source/drain SD2 and the second source/drain contact 182.

Each of the back-side wiring layer 110 and the front-side wiring layer 140 may include Co, Ni, W, Ti, Ta, Cu, Al, TiN, TaN, and/or a combination thereof.

In some embodiments, the first channel MBC1 of the first FET 120 and the second channel MBC2 of the second FET 130 may include the same material, for example, Si. In other embodiments, the first channel MBC1 and the second channel MBC2 may include different materials. For example, the first channel MBC1 may include SiGe and the second channel MBC2 may include Si.

FIG. 4A is a plan view showing a hybrid tap cell of the multi-stack semiconductor device of FIG. 1. FIG. 4B is a cross-sectional view taken along line II-II′ in FIG. 4A. FIG. 4C is a cross-sectional view taken along line III-III′ in FIG. 4A.

For convenience of explanation, description is given with reference to FIG. 1 and details already described with reference to FIG. 1 are briefly described or omitted.

Referring to FIGS. 4A to 4C together, in the multi-stack semiconductor device 100 according to some embodiments, the hybrid tap cell HTC may be arranged for every several to several tens of CPPs in the first horizontal direction (X direction).

For example, the hybrid tap cell HTC may be arranged for every 60 CPPs in the first horizontal direction (X direction). The hybrid tap cell HTC may include the power tap cell PTC and the signal tap cell STC in one cell region. The first through structure 150 that connects the first back-side power line 112 to the front-side power line 142 in the vertical direction (Z direction) may be arranged in the power tap cell PTC. As shown in FIG. 4B, single diffusion breaks SDBs may be arranged on both sides of the power tap cell PTC in the first horizontal direction (X direction).

In some embodiments, as shown in FIG. 4A, the hybrid tap cell HTC may have a width which is about a half of a horizontal width of one logic cell LC in the first horizontal direction (X direction). Therefore, as the width of the hybrid tap cell HTC is defined as about a half of one logic cell LC, the hybrid tap cell HTC may be arranged between first and second single diffusion breaks SDB1 and SDB2 that are spaced apart from each other in the first horizontal direction (X direction). For example, the first single diffusion break SDB1 and the second single diffusion break SDB2 may intersect the power tap cell PTC and the signal tap cell STC.

In other embodiments, as shown in FIG. 1, the hybrid tap cell HTC may have a width that is the same as the horizontal width of one logic cell LC in the first horizontal direction (X direction). Therefore, as the width of the hybrid tap cell HTC is defined as the same as one logic cell LC, one single diffusion break SDB may be further arranged between the first and second single diffusion breaks SDB1 and SDB2.

For convenience of explanation and understanding, FIGS. 4A to 4C illustrate an embodiment in which the width of the hybrid tap cell HTC is defined as about a half of a horizontal width of one logic cell LC. A person skilled in the art may understand other embodiments through description of some embodiments.

The first through structure 150 may be arranged in a portion where the front-side power line 142 overlaps the power tap cell PTC, and the second through structure 160 may be arranged in a portion where the plurality of front-side signal lines 144 overlap the signal tap cell STC.

The single diffusion break SDB may have substantially the same width as the gates Gc, Go1, and Go2 in the first horizontal direction (X direction). For example, in the single diffusion break SDB, a dielectric layer having substantially the same width as gates may separate the actives ACT. For example, the single diffusion break SDB may include silicon nitride or silicon oxynitride.

The first through structure 150 arranged in the power tap cell PTC may include a stacked structure of an upper via 157 and a first through electrode 151. In other words, the front-side power line 142 may be connected to the upper via 157 to contact the same. In some embodiments, a first barrier metal 151B may be arranged on an outer periphery of the first through electrode 151. In other embodiments, the first barrier metal 151B may not be formed.

In the multi-stack semiconductor device 100 according to some embodiments, the first through structure 150 may correspond to a front-side through electrode. The front-side through electrode may refer to a through electrode formed from the top to the bottom. Accordingly, as shown in FIG. 4B, the front-side through electrode may be wide at the top and narrow at the bottom. In some embodiments, each of the upper via 157, the first through electrode 151, and the first barrier metal 151B constituting the first through structure 150 may include, but is not limited to, Co, Ni, W, Ti, Ta, Cu, Al, TiN, TaN, and/or a combination thereof.

The second through structure 160 arranged in the signal tap cell STC may include a stacked structure of an upper via 167, an upper contact 165, a second through electrode 161, a lower source/drain contact 163b, a lower contact 165b, and a lower via 167b. In other words, the plurality of front-side signal lines 144 may be connected to the upper via 167 to contact the same. For example, the upper via 167 may extend in the second horizontal direction (Y direction) and may contact at least one of the plurality of front-side signal lines 144. In the multi-stack semiconductor device 100 according to some embodiments, the second through electrode 161 may correspond to a front-side through electrode. The front-side through electrode may refer to a through electrode formed from the top to the bottom. Accordingly, as shown in FIG. 4C, the front-side through electrode may be wide at the top and narrow at the bottom. In some embodiments, each of the upper via 167, the upper contact 165, the second through electrode 161, the lower source/drain contact 163b, the lower contact 165b, and the lower via 167b constituting the second through structure 160 may include, but is not limited to, Co, Ni, W, Ti, Ta, Cu, Al, TiN, TaN, and/or a combination thereof.

As shown in FIG. 4B and FIG. 4C, the dielectric layer DL may be arranged between the first FET 120 and the second FET 130, and the lower dielectric layer LL may be arranged below the first FET 120. Each of the dielectric layer DL and the lower dielectric layer LL may include silicon oxide, SiOC, SiOCN, SiCN, SiBN, SION, SiBCN, SiOF, SiOCH, or a combination thereof. In some embodiments, the dielectric layer DL and the lower dielectric layer LL may include the same dielectric material.

As shown in FIGS. 4B and 4C, the second source/drain SD2 of the second FET 130 may be connected to the front-side signal line 144 of the front-side wiring layer 140 through the upper source/drain contact 163, the upper contact 165, and the upper via 167. In some embodiments, the second source/drain contact 182 may include the upper source/drain contact 163, the upper contact 165, and the upper via 167.

The front-side wiring layer 140 on the left side is different from the front-side wiring layer 140 on the right side with reference to the left dash-dotted line among the dashed-dotted lines defining the power tap cell PTC region in FIG. 4B. The left side may correspond to the front-side signal line 144 and the right side may correspond to the front-side power line 142.

The first through structure 150 may not pass through the first and second sources/drains SD1 and SD2, and the second through structure 160 may pass (i.e., extend) through the second source/drain SD2. The second through structure 160 may also extend into the first source/drain SD1. A first length (i.e., a first thickness) of the first through electrode 151 constituting the first through structure 150 in the vertical direction (Z direction) may be greater than a second length (i.e., a second thickness) of the second through electrode 161 constituting the second through structure 160 in the vertical direction (Z direction). Accordingly, a bottom surface of the first through electrode 151 may be in direct contact with the first back-side power line 112, and a bottom surface of the second through electrode 161 may be located inside the first source/drain SD1 of the first FET 120. Each of the second source/drain SD2 through which the second through electrode 161 passes and the first source/drain SD1 in which the bottom surface of the second through electrode 161 is located may be a dummy source/drain (i.e., a dummy source/drain region) that does not function as an active source/drain of a transistor. In other words, the corresponding first source/drain SD1 may be referred to as a first dummy source/drain or a lower dummy source/drain, and the corresponding second source/drain SD2 may be referred to as a second dummy source/drain or an upper dummy source/drain. The upper dummy source/drain SD2 may be spaced apart from the second source/drain SD2 in the first horizontal direction (X direction), and the lower dummy source/drain SD1 may be spaced apart from the first source/drain SD1 in the first horizontal direction (X direction).

Each of the first dummy source/drain and the second dummy source/drain may include one of Si or SiGe. For example, both of the first dummy source/drain and the second dummy source/drain may include Si, or both of the first dummy source/drain and the second dummy source/drain may include SiGe. In some embodiments, the first dummy source/drain may include any one of Si or SiGe, and the second dummy source/drain may include the other one of Si or SiGe.

In other words, the upper vias 157 and 167 may be arranged above the first through electrode 151 and the second through electrode 161, respectively, and the lower via 167b may be arranged below the second through electrode 161. However, a lower via may not be arranged below the first through electrode 151.

In some embodiments, the second through electrode 161 and the lower source/drain contact 163b may be electrically connected through the first source/drain SD1. In addition, the second through electrode 161 may pass through the second source/drain SD2 and extend longitudinally in the second horizontal direction (Y direction) and may be arranged so that a part of the left side surface thereof and a part of the right side surface thereof are in contact with the second source/drain SD2 in the first horizontal direction (X direction). In addition, the lower source/drain contact 163b may pass through a bottom surface of the first source/drain SD1 and extend into the first source/drain SD1 and may be arranged so that a part of the left side surface thereof and a part of the right side surface thereof are in contact with the first source/drain SD1 in the first horizontal direction (X direction). In other words, the bottom surface of the second through electrode 161 and a top surface of the lower source/drain contact 163b may be located inside the first source/drain SD1.

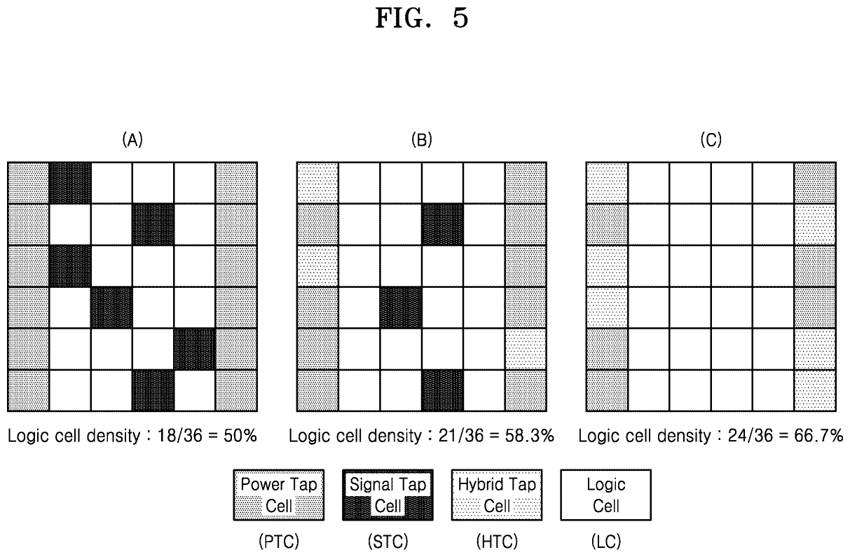

FIG. 5 is a conceptual diagram showing arrangement structures of different types of cells.

FIG. 5 is a schematic diagram which compares the distribution density of the logic cells LCs when power tap cells PTCs and signal tap cells STCs are independently arranged with the distribution density of the logic cells LCs when hybrid tap cells HTCs are included.

First, it is simply assumed that unit cells are arranged in a 6×6 matrix and the total number of unit cells is 36.

As shown in (A) of FIG. 5, when the power tap cells PTCs are arranged at both ends and the plurality of signal tap cell STCs are arranged between the logic cells LCs, only 18 unit cells can be occupied by the logic cells LCs. In other words, the number of logic cell LCs among a total of 36 unit cells is 18, so the distribution density of the logic cells LCs is 50%.

As shown in (B) of FIG. 5, when some of the power tap cells PTCs and some of the hybrid tap cells HTCs are arranged at both ends, and a small number of signal tap cell STCs are arranged between the logic cell LCs, the number of unit cells which can be occupied by the logic cells LCs corresponds to 21. In other words, the number of logic cell LCs among a total of 36 unit cells is 21, so the distribution density of the logic cells LCs is 58.3%.

As in shown in (C) of FIG. 5, when some of the power tap cells PTCs and some of the hybrid tap cells HTCs are arranged at both ends and no signal tap cells STCs are arranged between the logic cells LCs, the number of unit cells which can be occupied by the logic cells LCs corresponds to 24. In other words, the number of logic cell LCs among a total of 36 unit cells is 24, so the distribution density of the logic cells LCs is 66.7%.

As schematically seen through these simple unit cell arrangement structures, the difference between the distribution density (50%) of the logic cells LCs when the power tap cells PTCs and the signal tap cells STCs are independently arranged and the distribution density (66.7%) of the logic cells LCs when the hybrid tap cells HTCs are included is 16.7%.

Ultimately, the multi-stack semiconductor device 100 (see FIGS. 1 to 4C) according to the inventive concepts has an effect of increasing the integration because the area of the logic cells LCs can be sufficiently secured by using the hybrid tap cells HTCs including the power tap cells PTCs and the signal tap cells STCs in one cell region.

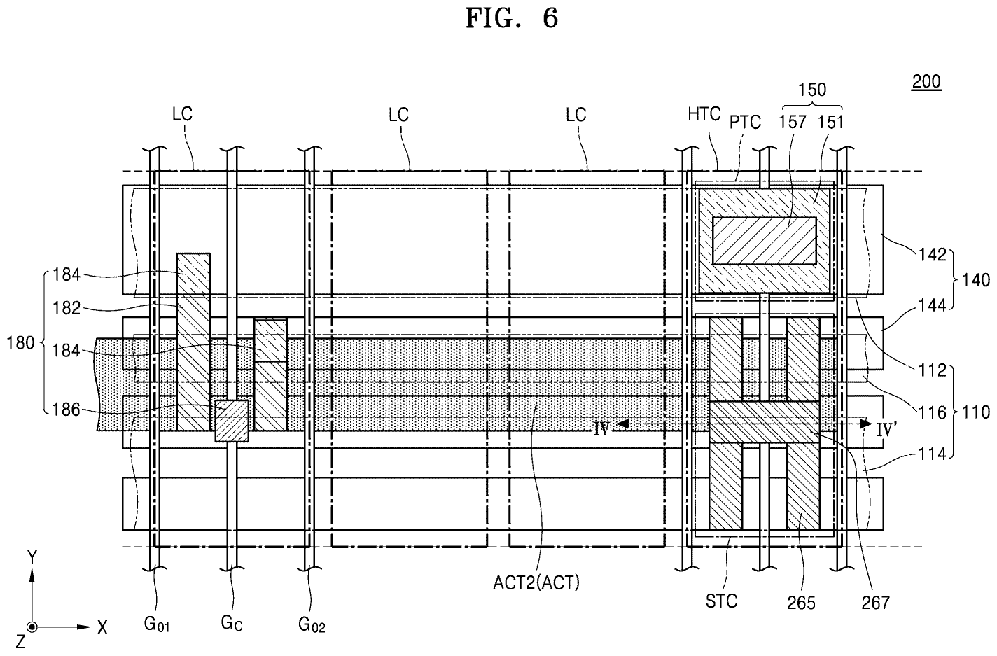

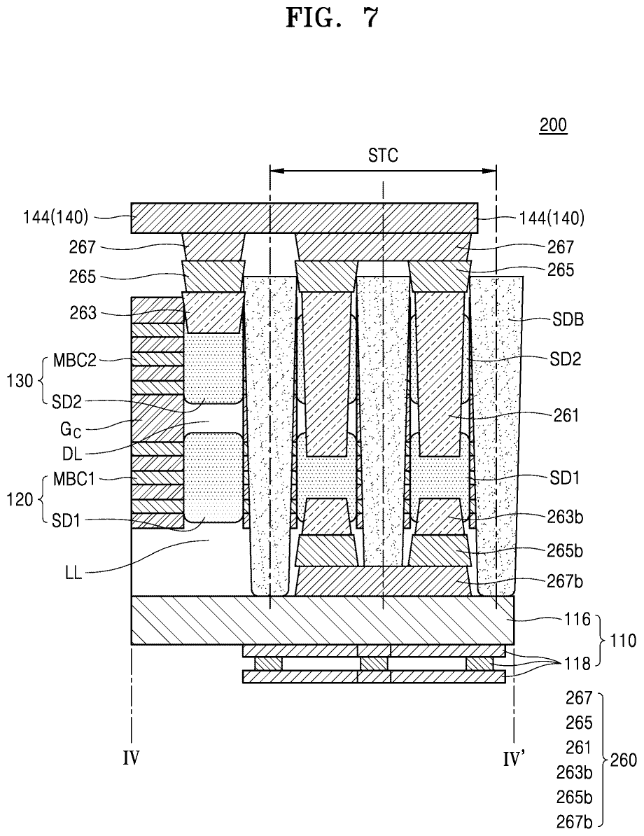

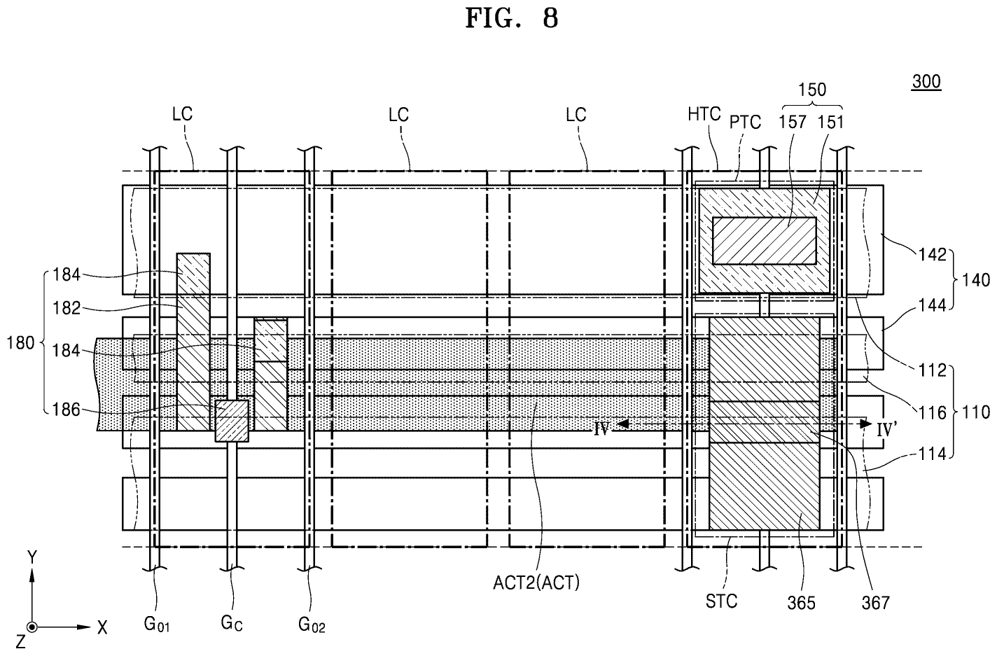

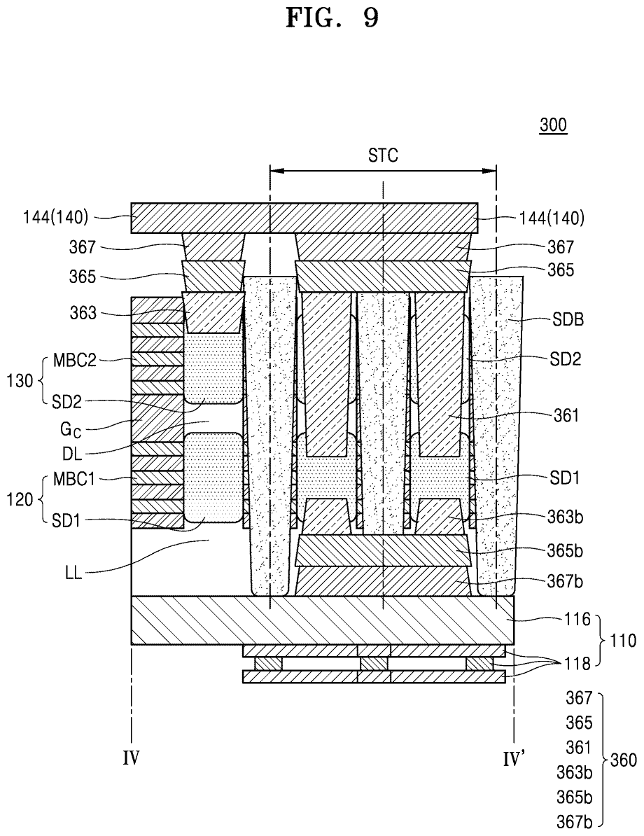

FIGS. 6 to 10 are diagrams of multi-stack semiconductor devices according to some embodiments. FIG. 7 is a cross-sectional view taken along line IV-IV′ in FIG. 6, and FIG. 9 is a cross-sectional view taken along line IV-IV′ in FIG. 8.

Most of the components constituting the multi-stack semiconductor devices 200, 300, and 400 to be described below and the materials constituting the components are substantially the same as or similar to those described above with reference to FIGS. 1 to 4C. Therefore, for convenience of explanation, differences from the multi-stack semiconductor device 100 described above may be mainly described.

Referring to FIGS. 6 and 7 together, the multi-stack semiconductor device 200 according to some embodiments may include a back-side wiring layer 110, a front-side wiring layer 140, a first through structure 150, and a second through structure 260.

The multi-stack semiconductor device 200 according to some embodiments may include two second through structures 260 corresponding to one first through structure 150. The two second through structures 260 may each include a stacked structure of an upper via 267, an upper contact 265, a second through electrode 261, a lower source/drain contact 263b, a lower contact 265b, and a lower via 267b.

The other components of the second through structure 260 except for the upper via 267 and the lower via 267b may be spaced apart from each other in the first horizontal direction (X direction) and may extend longitudinally in the second horizontal direction (Y direction). The upper via 267 may extend longitudinally in the first horizontal direction (X direction) to connect the upper contacts 265 spaced apart from each other in the first horizontal direction (X direction). Additionally, the lower via 267b may extend longitudinally in the first horizontal direction (X direction) to connect the lower contacts 265b spaced apart from each other in the first horizontal direction (X direction).

In a plan view, the two second through structures 260 may be formed to have an H-shape. In other words, some of the plurality of front-side signal lines 144 may be electrically connected with both of the second through structures 260 through the upper via 267.

As shown in FIG. 7, the second source/drain SD2 of the second FET 130 may be connected to the front-side signal line 144 of the front-side wiring layer 140 through the upper source/drain contact 263, the upper contact 265, and the upper via 267.

Referring to FIGS. 8 and 9 together, the multi-stack semiconductor device 300 according to some embodiments may include a back-side wiring layer 110, a front-side wiring layer 140, a first through structure 150, and a second through structure 360.

The multi-stack semiconductor device 300 according to some embodiments may include two second through structures 360 corresponding to one first through structure 150. The two second through structures 360 may each include a stacked structure of an upper via 367, an upper contact 365, a second through electrode 361, a lower source/drain contact 363b, a lower contact 365b, and a lower via 367b.

The other components of the second through structure 360 except for the upper via 367, the upper contact 365, the lower contact 365b, and the lower via 367b may be spaced apart from each other in the first horizontal direction (X direction) and may extend longitudinally in the second horizontal direction (Y direction). The upper via 367 and the upper contact 365 may extend longitudinally in the first horizontal direction (X direction) to connect the second through electrodes 361 spaced apart from each other in the first horizontal direction (X direction). In addition, each of the upper contact 365 and the lower contact 365b may extend longitudinally in the second horizontal direction (Y direction). Additionally, the lower contact 365b and the lower via 367b may extend longitudinally in the first horizontal direction (X direction) to connect the lower source/drain contacts 363b spaced apart from each other in the first horizontal direction (X direction).

In a plan view, a horizontal width of the first through structure 150 in the first horizontal direction (X direction) may be substantially the same as a horizontal width of the second through structure 360 in the first horizontal direction (X direction), and the two second through structures 360 may be formed to have an I-shape. In other words, the plurality of front-side signal lines 144 may be electrically connected with both of the second through structures 360 through the upper via 367.

As shown in FIG. 9, the second source/drain SD2 of the second FET 130 may be connected to the front-side signal line 144 of the front-side wiring layer 140 through the upper source/drain contact 363, the upper contact 365, and the upper via 367.

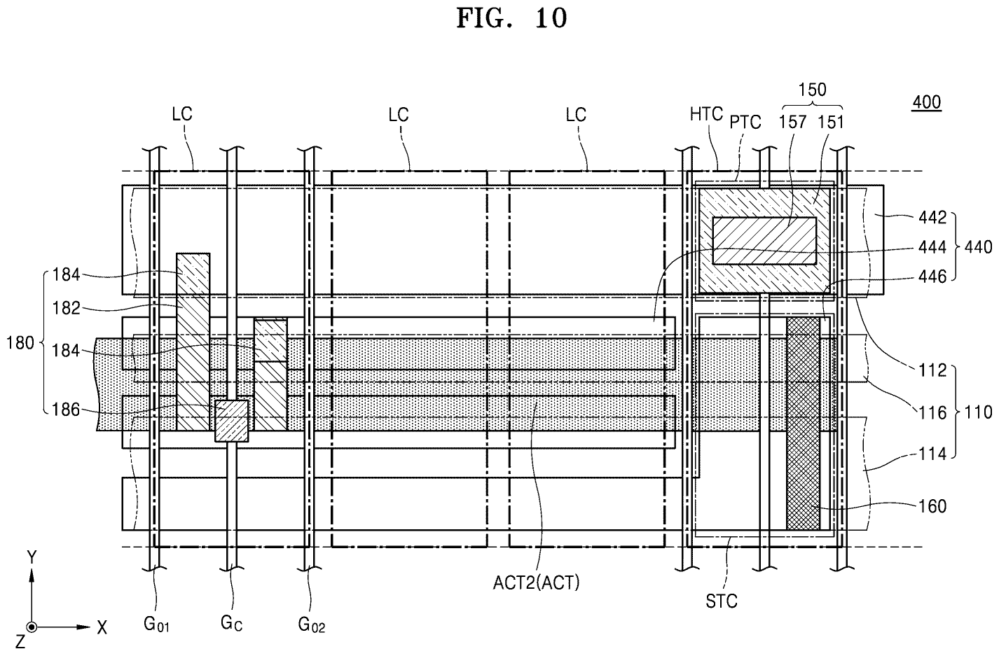

Referring to FIG. 10, the multi-stack semiconductor device 400 according to some embodiments may include a back-side wiring layer 110, a front-side wiring layer 440, a first through structure 150, and a second through structure 160.

In the multi-stack semiconductor device 400 according to some embodiments, the front-side wiring layer 440 may include a front-side power line 442, a plurality of straight front-side signal lines 444, and an L-shaped front-side signal line 446 of which an end portion has a relatively large area.

The front-side power line 442 may be referred to as a first front-side line, and the plurality of straight front-side signal lines 444 and the L-shaped front-side signal line 446 may be referred to as second front-side lines. In other words, the end portion of the L-shaped front-side signal line 446 that is one of the second front-side lines has a greater area than the other end portion of the L-shaped front-side signal line 446, and the second through structure 160 may be arranged to be in contact with the end portion of the L-shaped front-side signal line 446. For example, the upper via 167 (see FIG. 4C) may contact the end portion of the L-shaped front-side signal line 446. By increasing the contact area in this manner, the contact resistance may be reduced.

The front-side power line 442 may extend in the first horizontal direction (X direction). The front-side power line 442 may provide the second FET 130 with a first power, e.g., a power of a negative (−) potential or a ground potential. The front-side power line 442 may be connected to the first back-side power line 112 through a first through structure 150 arranged in the power tap cell PTC.

The plurality of straight front-side signal lines 444 and the L-shaped front-side signal line 446 may be spaced apart from each other in the second horizontal direction (Y direction) and may extend in the first horizontal direction (X direction). The L-shaped front-side signal line 446 may be connected to the second source/drain SD2 of the second FET 130 through the second through structure 160. Signals may be input and output to the second FET 130 through the L-shaped front-side signal line 446.

While the inventive concepts have been particularly shown and described with reference to example embodiments thereof, it will be understood that various changes in form and details may be made therein without departing from the scope of the following claims.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof. In addition, it will be understood that, although the terms “first”, “second”, “third”, etc. may be used herein to describe various elements, these elements should not be limited by these terms. Rather, these terms are only used to distinguish one element from another. For example, a first element could be termed a second element, and, similarly, a second element could be termed a first element, without departing from the scope of the present disclosure.

What is claimed is:

1. A multi-stack semiconductor device comprising:
a back-side wiring layer having a first back-side line and a second back-side line each extending in a first horizontal direction;
a first field-effect transistor (FET) on the back-side wiring layer and including a lower source/drain region;
a second FET on the first FET and including an upper source/drain region on the lower source/drain region; and
a hybrid tap cell having a first tap cell and a second tap cell that are adjacent to each other in a second horizontal direction perpendicular to the first horizontal direction,
wherein the first tap cell comprises a first through structure electrically connected to the first back-side line in a vertical direction, and
wherein the second tap cell comprises a second through structure extending through an upper dummy source/drain region and electrically connected to the second back-side line in the vertical direction, where the upper dummy source/drain region is spaced apart from the upper source/drain region in the first horizontal direction.

2. The multi-stack semiconductor device of claim 1, further comprising a front-side wiring layer on the second FET and having a first front-side line and a second front-side line each extending in the first horizontal direction, wherein the first front-side line and the first back-side line overlap the first tap cell in the vertical direction, and the second front-side line and the second back-side line overlap the second tap cell in the vertical direction.

3. The multi-stack semiconductor device of claim 2, wherein the first front-side line and the first back-side line overlap each other in the vertical direction and are electrically connected to each other through the first through structure,
wherein the second front-side line and the second back-side line overlap each other in the vertical direction and are electrically connected to each other through the second through structure,
wherein the first through structure comprises a stacked structure including a first upper via and a first through electrode, and
wherein the second through structure comprises a stacked structure including a second upper via, an upper contact, a second through electrode, a lower source/drain contact, a lower contact, and a lower via.

4. The multi-stack semiconductor device of claim 3, wherein a first thickness of the first through electrode in the vertical direction is greater than a second thickness of the second through electrode in the vertical direction.

5. The multi-stack semiconductor device of claim 3, wherein a bottom surface of the first through electrode is in direct contact with the first back-side line, and a bottom surface of the second through electrode is in a lower dummy source/drain region, and
wherein the lower dummy source/drain region is spaced apart from the lower source/drain region in the first horizontal direction.

6. The multi-stack semiconductor device of claim 2, wherein, in the hybrid tap cell, the first tap cell comprises a power tap cell, and the second tap cell comprises a signal tap cell.

7. The multi-stack semiconductor device of claim 6, wherein a plurality of logic cells are on a side of the hybrid tap cell.

8. The multi-stack semiconductor device of claim 7, wherein the first front-side line, the first back-side line, and the first through structure comprise a power distribution network, and
wherein the second front-side line, the second back-side line, and the second through structure comprise a signal distribution network.

9. The multi-stack semiconductor device of claim 1, further comprising a first single diffusion break and a second single diffusion break extending in the second horizontal direction and spaced apart from each other in the first horizontal direction, wherein the first through structure and the second through structure are between the first single diffusion break and the second single diffusion break.

10. The multi-stack semiconductor device of claim 9, wherein the first single diffusion break and the second single diffusion break intersect the first tap cell and the second tap cell.

11. A multi-stack semiconductor device comprising:
a hybrid tap cell on a side of a plurality of logic cells and having a power tap cell and a signal tap cell in a cell region;
a back-side wiring layer having a back-side power line and a back-side signal line each extending in a first horizontal direction, in the plurality of logic cells and the hybrid tap cell;
a first field-effect transistor (FET) on the back-side wiring layer and a second FET on the first FET, in one or more of the plurality of logic cells;
a front-side wiring layer on the second FET and having a front-side power line and a plurality of front-side signal lines each extending in the first horizontal direction, in the plurality of logic cells and the hybrid tap cell;
a power through structure electrically connecting the front-side power line to the back-side power line in a vertical direction, in the power tap cell of the hybrid tap cell; and
a signal through structure electrically connecting at least one of the plurality of front-side signal lines to the back-side signal line in the vertical direction, in the signal tap cell of the hybrid tap cell.

12. The multi-stack semiconductor device of claim 11, wherein each of the first FET and the second FET comprises:
a gate extending in a second horizontal direction perpendicular to the first horizontal direction;
source/drain regions on opposite sides of the gate in the first horizontal direction; and
a channel region between the source/drain regions and at least partially surrounded by the gate,
wherein first ones of the source/drain regions comprise an active source/drain region and second ones of the source/drain regions comprise a dummy source/drain region, and
wherein the power through structure does not extend into the dummy source/drain region, and the signal through structure extends into the dummy source/drain region.

13. The multi-stack semiconductor device of claim 12, wherein the power through structure comprises a stacked structure including a first upper via and a first through electrode, and
wherein the signal through structure comprises a stacked structure including a second upper via, an upper contact, a second through electrode, a lower source/drain contact, a lower contact, and a lower via.

14. The multi-stack semiconductor device of claim 13, wherein the second upper via extends in the second horizontal direction and contacts at least one of the plurality of front-side signal lines.

15. The multi-stack semiconductor device of claim 13, wherein an end portion of a first one of the plurality of front-side signal lines has a greater area than an end portion of a second one of the plurality of front-side signal lines, and
wherein the second upper via contacts the end portion of the first one of the plurality of front-side signal lines.

16. A multi-stack semiconductor device comprising:
a back-side wiring layer having a first back-side line and a second back-side line each extending in a first horizontal direction;
a first field-effect transistor (FET) on the back-side wiring layer;
a second FET on the first FET;
a front-side wiring layer on the second FET and having a first front-side line and a second front-side line each extending in the first horizontal direction;
a hybrid tap cell comprising, in a cell region, a power tap cell and a signal tap cell that are adjacent to each other in a second horizontal direction perpendicular to the first horizontal direction;
a first through structure electrically connecting the first front-side line to the first back-side line in a vertical direction and comprising a first upper via and a first through electrode in the power tap cell; and
a second through structure electrically connecting the second front-side line to the second back-side line in the vertical direction and comprising a second upper via, an upper contact, a second through electrode, a lower source/drain contact, a lower contact, and a lower via in the signal tap cell,
wherein each of the first FET and the second FET comprises:
a gate extending in the second horizontal direction;
source/drain regions on opposite sides of the gate in the first horizontal direction; and
a channel region between the source/drain regions and at least partially surrounded by the gate, wherein first ones of the source/drain regions comprise an active source/drain region and second ones of the source/drain regions comprise a dummy source/drain region, and
wherein the first through electrode does not extend into the dummy source/drain region, and the second through electrode extends into the dummy source/drain region.

17. The multi-stack semiconductor device of claim 16, wherein a first thickness of the first through electrode in the vertical direction is greater than a second thickness of the second through electrode in the vertical direction.

18. The multi-stack semiconductor device of claim 16, wherein the channel region comprises a plurality of semiconductor patterns that are spaced apart from each other in the vertical direction, and the gate has a gate-all-around structure.

19. The multi-stack semiconductor device of claim 16, wherein the hybrid tap cell is arranged after every predetermined number of logic cells in the first horizontal direction.

20. The multi-stack semiconductor device of claim 16, further comprising a first single diffusion break and a second single diffusion break extending in the second horizontal direction and spaced apart from each other in the first horizontal direction, wherein the first through electrode and the second through electrode are between the first single diffusion break and the second single diffusion break, and the first single diffusion break and the second single diffusion break intersect the power tap cell and the signal tap cell.
